(19) United States
(12) Patent Application Publication
(10) Pub. No.: US 2008/0105960 A1
(43) Pub. Date: May 8, 2008

(54) Integrated Circuit Package and Method for Manufacturing an Integrated Circuit Package

(76) Inventors: Beng Keh See, Johor (MY); Tiam Sen Ong, Melaka (MY); Chee Chian Lim, Melaka (MY)

Correspondence Address: SLATER & MATSIL LLP, 17950 PRESTON ROAD, SUITE 1000, DALLAS, TX, 75252, US

(21) Appl. No.: 11/969,739

(22) Filed: Jan. 4, 2008

Related U.S. Application Data
(63) Continuation of application No. PCT/SG2005/000221, filed on Jul. 6, 2005.

(51) Int. Cl. H01L 23/495

(52) U.S. Cl. 257/676

(57) ABSTRACT

An integrated circuit package includes: an integrated circuit having a surface at least partially covered by a metal layer; at least one connection point; at least one connector electrically connecting the integrated circuit with the at least one connection point; and encapsulating material encapsulating the at least one connector, at least some of the integrated circuit and at least some of the at least one connection point, such that a contact surface of the at least one connection point and the metal layer on the integrated circuit are exposed outside the encapsulating material.

This application is a continuation of co-pending International Application No. PCT/SG2005/000221, filed Jul. 6, 2005, which designated the United States and was published in English, of which application is incorporated herein by reference.

### TECHNICAL FIELD

The present invention relates to integrated circuit (IC) packages and methods for assembling IC packages.

### BACKGROUND

With the miniaturization of electronic devices and, in particular, the widespread popularity of portable electronic devices such as personal data organizers, mobile cellular telephones and portable computers, there is a need to reduce both the footprint and thickness of IC packages.

Traditional IC packages typically comprise an IC mounted onto a lead frame having a plurality of lead fingers for distributing electrical signals to the IC. The IC is electrically connected to inner portions of the lead fingers. An electrically insulating material encapsulates the IC and inner portions of the lead fingers while the outer portions of the lead fingers extend laterally out of the encapsulation material for connection to an external substrate such as a printed circuit board (PCB). However, while these traditional package styles are low cost and simple to manufacture, they also occupy a high footprint.

In order to meet the demand for smaller and slimmer package styles, semiconductor manufacturers have developed “leadless” package styles such as the thin small leadless package (TSLP) and quad flat no-lead package (QFN). In leadless package styles, there are no lead fingers extending laterally out of the encapsulating material. Instead, connection leads which provide the electrical connection between the packaged IC and an external substrate have exposed surfaces located on an exterior surface of the encapsulating material.

FIGS. 1a to 1h show a known process for building a conductive pad for an IC package. TSLP frames are typically manufactured in the form of an array comprising a plurality of frames, with the individual units then being separated. Typically, a TSLP frame will include a number of conductive pads but, for simplicity, only a single pad is shown in FIGS. 1a to 1h. First of all, a metal substrate 101 is provided, on which is laminated a dry film 103. This is shown in FIG. 1a. On the dry film 103, a photoresist 105 is provided, patterned so as to leave uncovered those portions where the conductive pads are to be provided. This is shown in FIG. 1b. Then, the structure is exposed to UV (shown in FIG. 1c) causing the portions of the dry film 103 not covered by photoresist 105 to be etched away. Then an acid etch is applied to remove the photoresist 105 as shown in FIG. 1d. Then, the nickel (Ni) bump can be built up in layers by plating, a first layer 107 being shown in FIG. 1e and first 107 and second 109 layers being shown in FIG. 1f. The dry film 103 acts as a protective hard mask, which prevents those portions of the substrate beneath the dry film from being plated. Then a layer 111 of gold (Au) is plated on the nickel layers as shown in FIG. 1g. The gold layer is required to protect the nickel from oxidation during the high temperatures reached during plating. Finally, the dry film 103 is stripped off to produce a nickel and gold conductive pad on metal substrate 101 as shown in FIG. 1h.

Once the TSLP frame has been formed as described with reference to FIGS. 1a to 1h, an IC package can be formed by packaging an IC onto the TSLP frame. FIGS. 2a to 2l show a known process for packaging an integrated circuit onto a TSLP frame. Referring to FIG. 2a, first of all a TSLP frame 201 is provided. In FIG. 2a, only one die pad 203 and one bond pad 205 on copper substrate 206 are shown but it will be appreciated that there will typically be at least one die pad and a plurality of bond pads. On die pad 203 is an integrated circuit die 207. Die 207 is attached to die pad 203 by dispensing a layer of epoxy glue onto the upper surface of the die pad 203 and attaching the die 207 to the epoxy glue layer. Then the epoxy glue is cured in nitrogen or forming gas at a temperature of between about 300° C. and 430° C., to hold die 207 in place on die pad 203.

Then, the die 207 is electrically connected to bond pad 205 (and other bond pads (not shown)) by a wire bond 209. This is shown in FIG. 2b. Then the die 207 and wire bonds 209 are encapsulated in an electrically insulating molding compound 211 as shown in FIG. 2c. Curing is carried out to harden the molding compound. In FIG. 2d, a laser marking process is then carried out to mark identification marks onto the molding compound surface. Then, the copper substrate 206 is removed by etching, as shown in FIG. 2e. The die pad 203, bond pad 205, die 207 and wire bond 209 are still encapsulated by the molding compound 211 but the bottom surfaces of the pads 203, 205 are exposed. Then, in FIG. 2f, a layer 213 of gold is deposited on the bottom surfaces of the pads 203, 205. The gold layer ensures good solder reflow when the TSLP package is soldered onto a substrate. The upper surface of the molding compound 211 is laminated with a support 215 (FIG. 2g) then dicing is carried out to separate the array into individual units (see FIG. 2h). After a visual inspection to check the quality of the gold plating 213 (see FIG. 2i), electrical testing (see FIG. 2j), UV irradiation (see FIG. 2k) and taping (see FIG. 2l), the TSLP package is ready.

There are a number of disadvantages of the processes described above with reference to FIGS. 1a to 1h and FIGS. 2a to 2l. Firstly, there are a large number of process steps required (in forming the pads and in manufacturing the package) which increases cycle time and hence the cost. Secondly, several raw materials (including gold to protect against oxidation during the plating process) are required which increases the cost. Also, the variety of process steps means that a variety of machines will be required. Finally, the resulting TSLP packages are quite thick and occupy a large footprint.

As already discussed, another type of leadless IC package is a QFN. FIGS. 3a to 3k show a known process for manufacturing a QFN package. In FIG. 3a, leadframe 301 is attached to a substrate 303 using adhesive lead tape 305. The leadframe 301 comprises a die pad portion 307, which is arranged to receive an IC die, and a plurality of lead finger portions 309, which are used to connect a packaged IC having an external substrate. The leadframe 301 is formed by etching or stamping a leadframe substrate. In FIG. 3b, an IC die 311 is attached to the die pad portion 307 of the leadframe 301. This may be by application of an epoxy glue layer followed by curing, as described previously with reference to FIG. 1b. Then, electrical contacts 315 on the IC die 311 are each connected to a respective lead finger portion by wire bonds 317. This is shown in FIG. 3c. Then, the leadframe 301, the IC die 311 and the wire bonds 317 are encapsulated in an electrically insulating molding compound 319. This is shown in FIG. 3d. Then a curing process is carried out to harden molding compound 319. In FIG. 3e, the substrate 303 is removed from the molding compound by peeling away the substrate. This exposes the undersides of the die pad portion 307 and the lead finger portions 309. In FIG. 3f, a cleaning process is carried out to remove any remaining residue from the adhesive tape and then the exposed undersides of the leadframe are plated with a conductive material, e.g., silver (not shown) to reduce the electrical resistance of the lead finger portions. In FIG. 3g, the top surface of the molding compound is laminated with a support 321. Then, the individual units are separated by dicing, as shown in FIG. 3h. After electrical testing (shown in FIG. 3i), pick and place is performed (shown in FIG. 3j). This involves using a push needle to push the unit from the UV tape and then pocketing it into a carrier tape. This is to make it easier for the resulting users. Then, tape and reel is performed (shown in FIG. 3k). This means that another tape or tapes will be used to seal the carrier tape to prevent the unit dropping out of the carrier tape. Then, the IC packages are ready. Visual inspection may also be included in the process but this is not shown in FIG. 3.

There are a number of disadvantages of the process described above with reference to FIGS. 3a to 3k. Firstly, the QFN packages are quite thick. Also, the QFN packages have a large footprint. Just as with the TSLP packages, a large number of process steps are required for manufacture.

### SUMMARY OF THE INVENTION

In one aspect, the invention provides an integrated circuit package and a method for manufacturing an integrated circuit package which mitigate or substantially overcome the problems of known arrangements described above.

According to an aspect of the invention, there is provided an integrated circuit package that includes an integrated circuit having a surface at least partially covered by a metal layer and at least one connection point. At least one connector electrically connects the integrated circuit with the at least one connection point. Encapsulating material encapsulates the at least one connector, at least some of the integrated circuit and at least some of the connection point(s), such that a contact surface of each connection point and the metal layer on the integrated circuit are exposed outside the encapsulating material.

Since the integrated circuit itself is at the exterior of the encapsulating material, so that the metal layer is exposed, the IC package can be much thinner than known IC packages.

The metal layer may be coated with a layer of oxidation resistant material. That oxidation resistant material may comprise a noble metal. The noble metal may be silver. Alternatively, the oxidation resistant material may comprise gold or tin or solder. The metal layer itself may comprise nickel and/or gold and/or silver.

The exposed contact surfaces of the at least one connection point may be coated with a layer of oxidation resistant material. That oxidation resistant material may comprise a noble metal. The noble metal may be silver. Alternatively, the oxidation resistant material may comprise gold or tin or solder.

In one embodiment, the at least one connection point comprises a non-layered drop of metal. In that embodiment, preferably the non-layered drop of metal is formed by stud-bumping, i.e., by melting a wire of metal into globules which solidify and form the connection points. Typically, the drops of metal comprise two globular portions, the upper portion being smaller than the lower portion, the lower portion being formed by the metal globule itself and the upper portion being formed by the flattened remnant of the metal wire. In one embodiment, the drops of metal comprise copper.

According to another aspect of the invention, there is also provided a method for manufacturing an integrated circuit package. An adhesive surface is provided and at least one connection point is formed on the adhesive surface. An integrated circuit has a surface at least partially covered by a metal layer. The metal layer on the integrated circuit is attached to the adhesive surface. The integrated circuit is electrically connected to the at least one connection point with at least one connector. Each connector, at least some of the integrated circuit and at least some of the at least one connection point are encapsulated with an encapsulating material. After the encapsulating step, the adhesive surface is removed so as to expose a contact surface of the at least one connection point and the metal layer on the integrated circuit.

Since the integrated circuit itself is attached to the adhesive surface, the resulting IC package can have a reduced height when compared with known IC packages. Obviously, the integrated circuit is attached to the adhesive surface and the connection point(s) are formed on the adhesive surface in such a way that the adhesive surface can be removed.

The adhesive surface may comprise a UV foil surface or a polyimide tape surface. The adhesive surface may be on a substrate arranged to support the at least one connection point and the integrated circuit.

The step of removing the adhesive surface may comprise peeling away the adhesive surface from the encapsulating material. In that case, if the adhesive surface is formed on a substrate, the substrate must be sufficiently flexible to allow it to be stripped or peeled away from the encapsulating material.

The metal layer on the integrated circuit may comprise nickel and/or gold and/or silver.

The method may further comprise, after the step of removing the adhesive surface, the step of coating the exposed metal layer with a layer of oxidation resistant material. The oxidation resistant material may comprise a noble metal, which may be silver.

The method may further comprise, after the step of removing the adhesive surface, the step of coating at least one of the exposed contact surfaces of the at least one connection point with a layer of oxidation resistant material. The oxidation resistant material may comprise a noble metal, which may be silver. Alternatively, the oxidation resistant material may comprise gold or tin or solder.

In one embodiment, the step of forming at least one connection point on the adhesive surface comprises: melting metal wire to form at least one globule; and pressing the at least one globule onto the adhesive surface to form the at least one connection point.

In that arrangement, the process for forming the connection point(s) is known in the art as stud-bumping. The resulting connection points are non-layered drops of metal.

According to an embodiment of the invention, there is also provided an integrated circuit package obtained by the method of the first aspect of the invention.

According to another aspect of the invention, there is provided an integrated circuit package that includes an integrated circuit and at least one connection point. The at least one connection point comprises a non-layered drop of metal. At least one connector electrically connects the integrated circuit with the at least one connection point. Encapsulating material encapsulates the at least one connector, at least some of the integrated circuit and at least some of the at least one connection point, such that a contact surface of the at least one connection point is exposed outside the encapsulating material.

The non-layered drop of metal is preferably formed by a process known in the art as stud-bumping. This comprises melting metal wire into globules which solidify to form the connection points. The solidified globules typically comprise two globular portions, the upper portion being formed from the squashed remains of the metal wire and the lower portion being formed by the globule itself, the upper portion being smaller than the lower portion. In one embodiment the drops of metal comprise copper.

The exposed contact surfaces of the at least one connection point may be coated with a layer of oxidation resistant material. The oxidation resistant material may comprise a noble metal. The noble metal may be silver. Alternatively, the oxidation resistant material may comprise gold or tin or solder.

In one embodiment, the integrated circuit has a surface at least partially covered by a metal layer. The metal layer may comprise nickel and/or silver and/or gold.

In that embodiment, the metal layer on the integrated circuit may be exposed outside the encapsulating material. The metal layer may be coated with a layer of oxidation resistant material. The oxidation resistant material may comprise a noble metal, which may be silver. Alternatively, the oxidation resistant material may comprise gold or tin or solder.

In another embodiment, the integrated circuit is attached to and electrically in contact with an integrated circuit connection point. In that embodiment, a contact surface of the integrated circuit connection point may be exposed outside the encapsulating material. The exposed contact surface of the integrated circuit connection point may be coated with a layer of oxidation resistant material. The oxidation resistant material may comprise a noble metal, which may be silver. Alternatively, the oxidation resistant material may comprise tin or solder or gold.

The integrated circuit connection point may be a non-layered drop of metal. In this case, the connection point is preferably formed by stud-bumping, as previously described.

Alternatively, the integrated circuit connection point may comprise a plurality of metal layers. In this case, the connection point is preferably built up a layer at a time, each layer being formed by plating.

According to another aspect of the invention, there is also provided a method for manufacturing an integrated circuit package. The method includes providing a substrate and melting metal wire to form at least one globule and pressing the at least one globule onto the substrate so that the at least one globule forms at least one connection point. An integrated circuit is electrically connected to the at least one connection point with at least one connector. An encapsulating material encapsulates the at least one connector, at least some of the integrated circuit and at least some of the at least one connection point. After the encapsulating step, the substrate is removed so as to expose a contact surface of the at least one connection point.

The method may further comprise, after the step of removing the substrate, the step of coating at least one of the exposed contact surfaces of the at least one connection point with a layer of oxidation resistant material. The oxidation resistant material may comprise a noble metal, which may be silver. Alternatively, the oxidation resistant material may comprise tin or solder or gold.

In one embodiment, the integrated circuit has a surface at least partially covered by a metal layer. The metal layer may comprise nickel and/or gold and/or silver.

In that embodiment, the method may further comprise, before the encapsulating step, the step of attaching the metal layer on the integrated circuit to the substrate, wherein, after the substrate is removed, the metal layer on the integrated circuit is exposed outside the encapsulating material.

In that case, the substrate preferably has an adhesive surface to which the metal layer on the integrated circuit is attached.

The method may further comprise the step of coating the exposed metal layer with a layer of oxidation resistant material. The oxidation resistant material may comprise a noble metal, which may be silver. Alternatively, the oxidation resistant material may comprise gold or tin or solder.

In an alternative embodiment, the method further comprises the step of forming an integrated circuit connection point on the substrate.

In that embodiment, the method may further comprise the step of attaching and electrically connecting the integrated circuit to the integrated circuit connection point.

In that embodiment, preferably, after the substrate is removed, a contact surface of the integrated circuit connection point is exposed outside the encapsulating material.

The method may further comprise the step of coating the exposed contact surface of the integrated circuit connection point with a layer of oxidation resistant material. The oxidation resistant material may comprise a noble metal, which may be silver. Alternatively, the oxidation resistant material may comprise gold or tin or solder.

The step of forming an integrated circuit connection point on the substrate may comprise: melting metal wire to form at least one globule; and pressing the at least one globule onto the substrate. Alternatively, the step of forming an integrated circuit connection point on the substrate may comprise plating a plurality of metal layers onto the substrate.

According to the invention, there is also provided an integrated circuit package obtained by the method of the second aspect of the invention.

Features described in relation to one aspect of the invention may also be applicable to another aspect of the invention.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1a to 1h show a known process for manufacturing a conductive pad;

FIGS. 2a to 2l show a known process for manufacturing a TSLP package;

FIGS. 3a to 3k show a known process for manufacturing a QFN package.

Exemplary embodiments of the invention will now be described with reference to FIGS. 4a, 4b, 5a, 5b, 6a to 6k, 7a to 7j and 8a to 8k, of which:

FIGS. 4a and 4b show a process for manufacturing a conductive pad;

FIGS. 5a and 5b show two arrangements of bumps formed by the process of FIGS. 4a and 4b;

FIGS. 6a to 6k show a process for manufacturing a TSLP package according to a first embodiment of the invention;

FIGS. 7a to 7j show a process for manufacturing a TSLP package according to a second embodiment of the invention; and

FIGS. 8a to 8k show a process for manufacturing a QFN package according to a third embodiment of the invention.

### DETAILED DESCRIPTION OF ILLUSTRATIVE EMBODIMENTS

FIGS. 4a and 4b show a process for forming a conductive pad, using a copper bumping machine. In this process, a single conductive pad is formed. First of all, a plastic substrate 401 is provided, on which is formed an adhesive layer 403 (for example of UV foil or polyimide tape). This is shown in FIG. 4a. Then, on the layer 403 a conductive pad in the form of a copper “bump” 405 is formed. This is shown in FIG. 4b.

The copper bump is produced by a bumping machine which uses copper wire to form globules of liquid copper which are pressed onto the layer 403 as the remainder of the wire is cut. This process is similar to a wire bonding process. The bumping is controlled by the rate of melting of the copper wire and the size of the capillary used for forming globules. Typically, each bump can be formed in about 0.05 s and the bumps can be positioned on the layer 403 to an accuracy of ±3.5 μm. Immediately after the wire is cut, the remnant of the wire remains at the top of the globule of copper so the top surface of the bump is then flattened so that the bump comprises two portions, the upper portion being formed by the remnants of the wire and the lower portion being formed from the metal globule itself. The overall shape resembles the usual shape of a brioche bread loaf. The flattening is commonly incorporated into the step of cutting off the wire. The layer 403 is adhesive so that the bumps will stick to the layer. If taller bumps are required, stacked bumps can be produced by repeating the wire melting and flattening steps a number of times.

The conductive pads described with reference to FIGS. 4a and 4b are copper but they could equally be another metal, for example, gold. Copper has the advantage that it is cheaper than gold and also has better electrical properties.

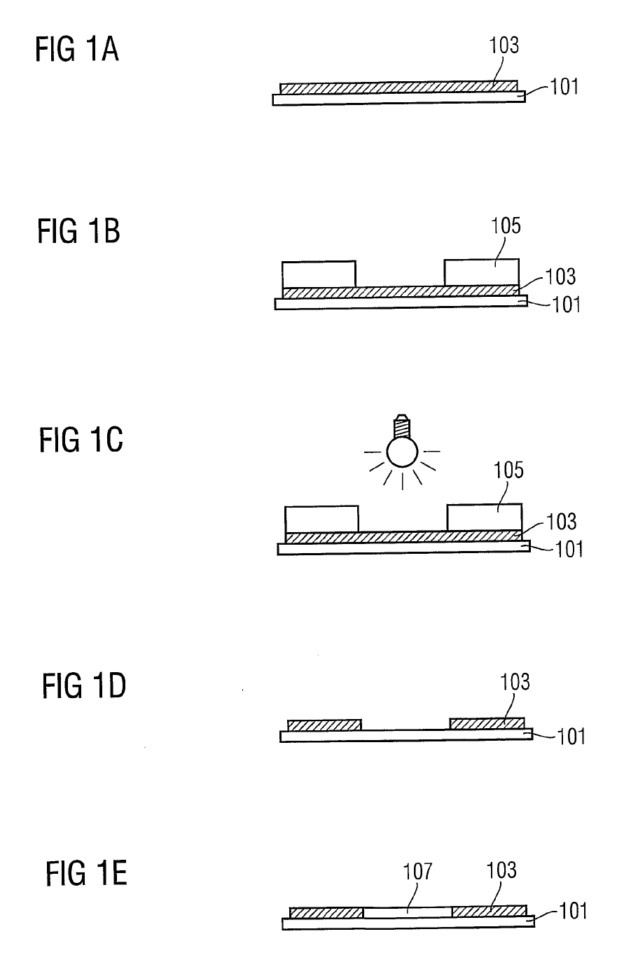

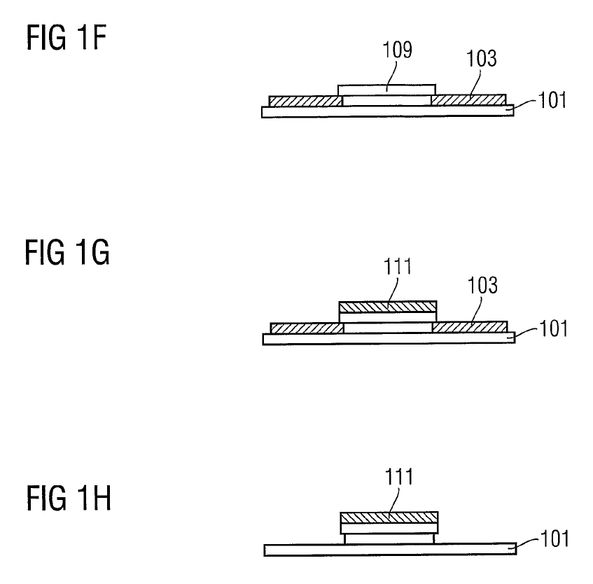

If we compare the two step process shown in FIGS. 4a and 4b with the many stage process shown in FIGS. 1a to 1h, we see there are many advantages. Firstly, plating is not involved so the substrate does not need to be metal but can be any organic or inorganic material (including metal, LJV foil, polyimide tape) which will hold the bump. Secondly, the process is very quick (fewer process steps) so process time is decreased. Thirdly, no galvanic process to etch away the metal substrate is required; the organic substrate can be removed manually after a subsequent molding process. The process is a dry process. Also, since the bumps are created at room temperature, no gold plating is required to protect the bumps from oxidation, this reduces costs. The only raw material required is copper wire for the bumping machine. Also, since one bumping machine can typically produce around 225 million units per year, the process is cheaper. The resulting copper bumps also have better electrical performance than the plated bumps.

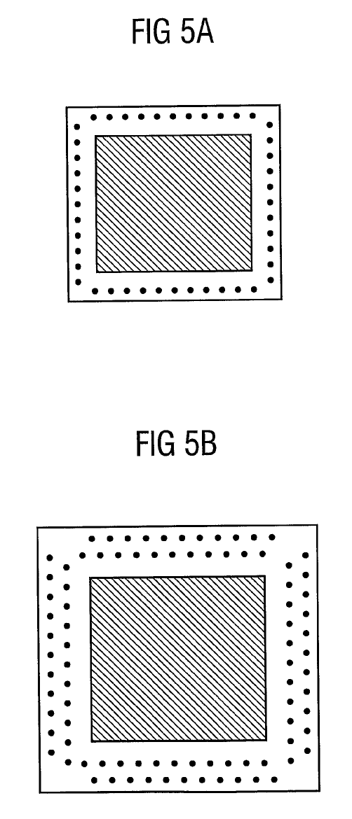

The arrangement of bumps can be programmed into the bumping machine. Two different arrangements are shown in FIGS. 5a and 5b. FIG. 5a shows a standard footprint for a QFN with a plurality of bumps 501. FIG. 5b shows a stagger footprint for a stacked QFN with a plurality of bumps 501.

Thus, another advantage of using a bumping machine is that the arrangement of the bumps can easily be changed by reprogramming the machine. In addition, the size of each bump can easily be changed.

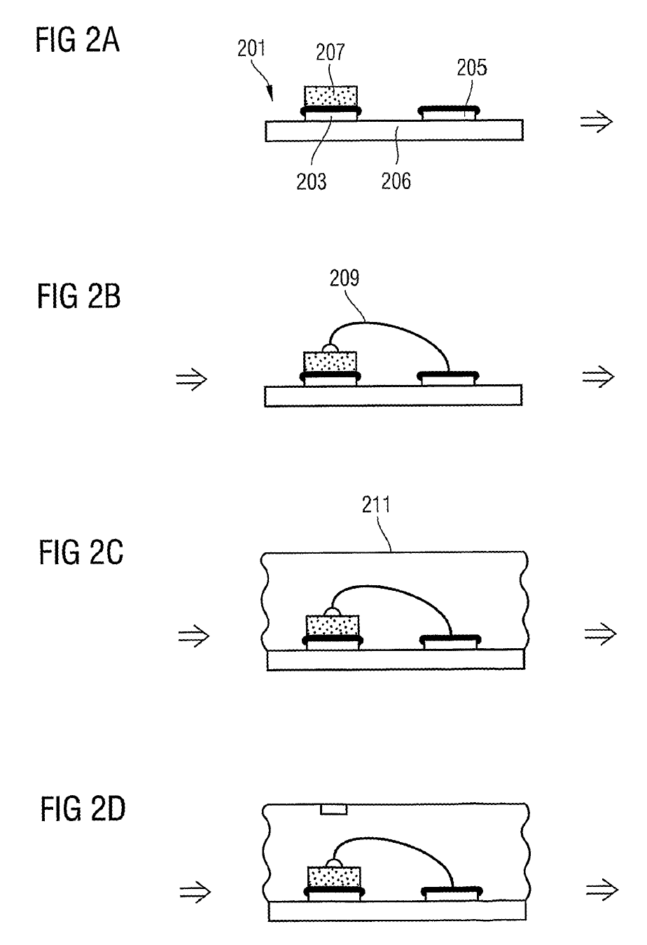

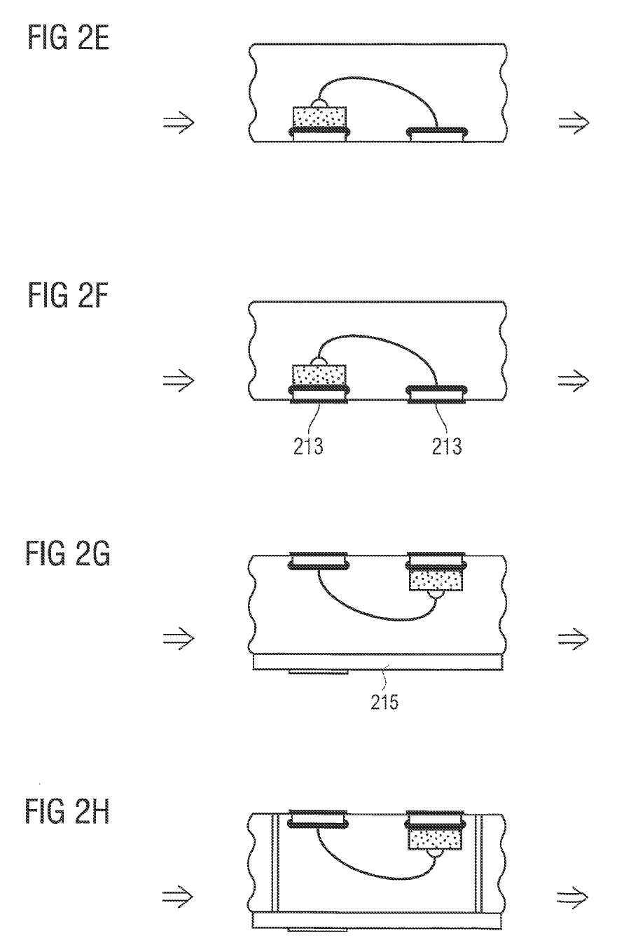

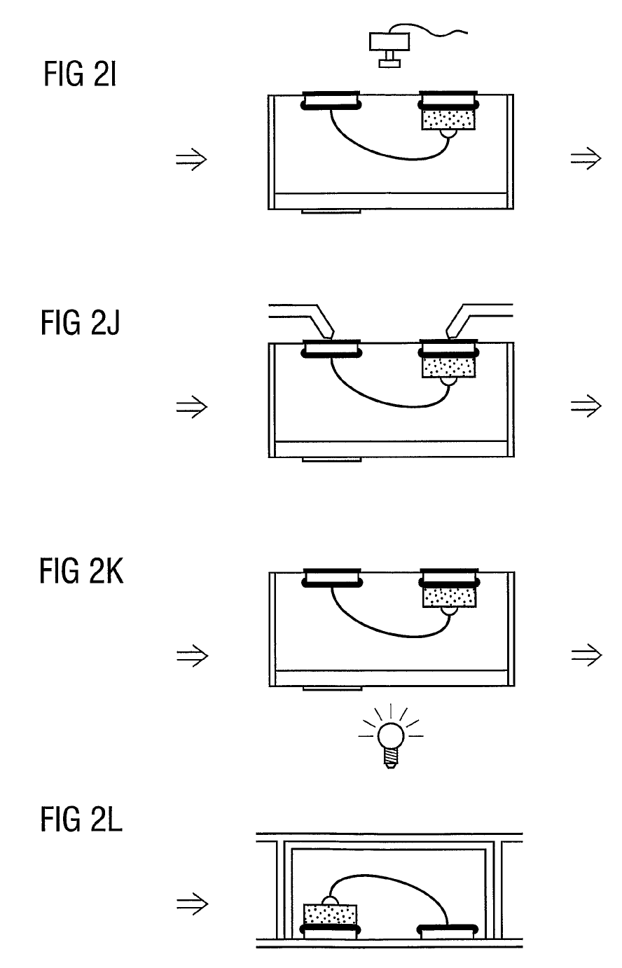

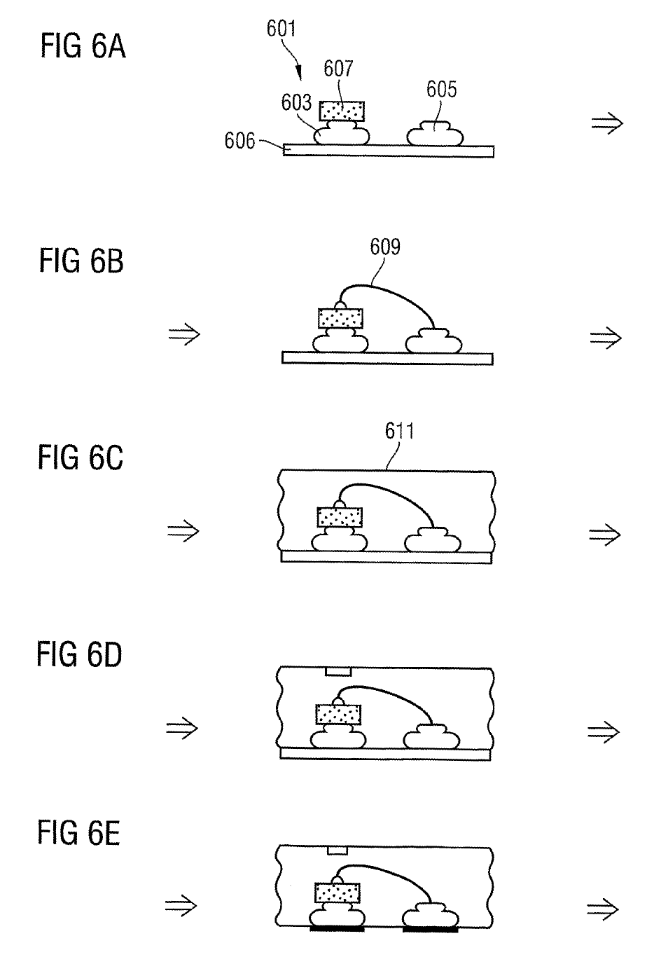

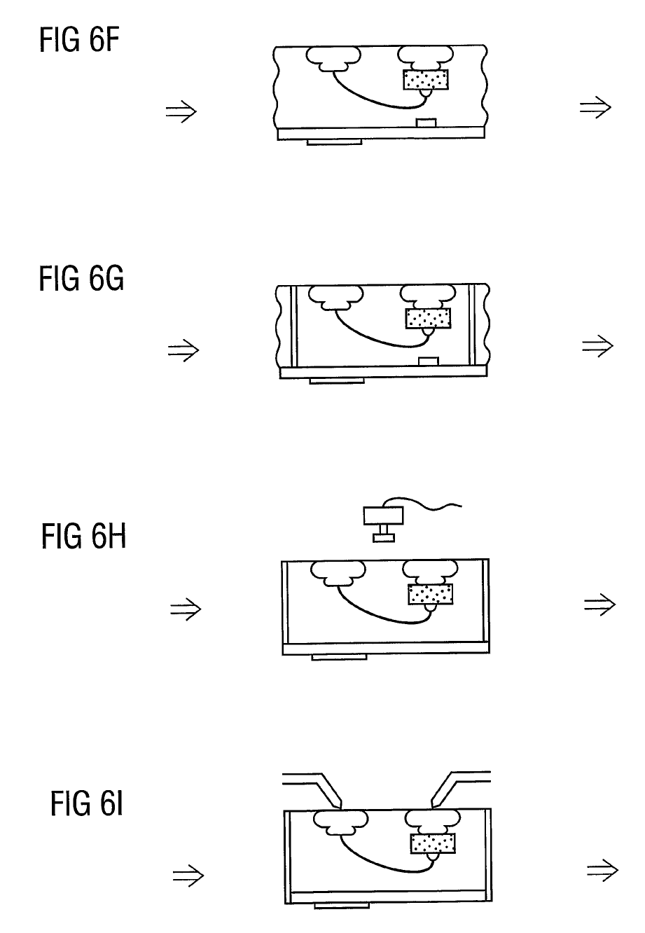

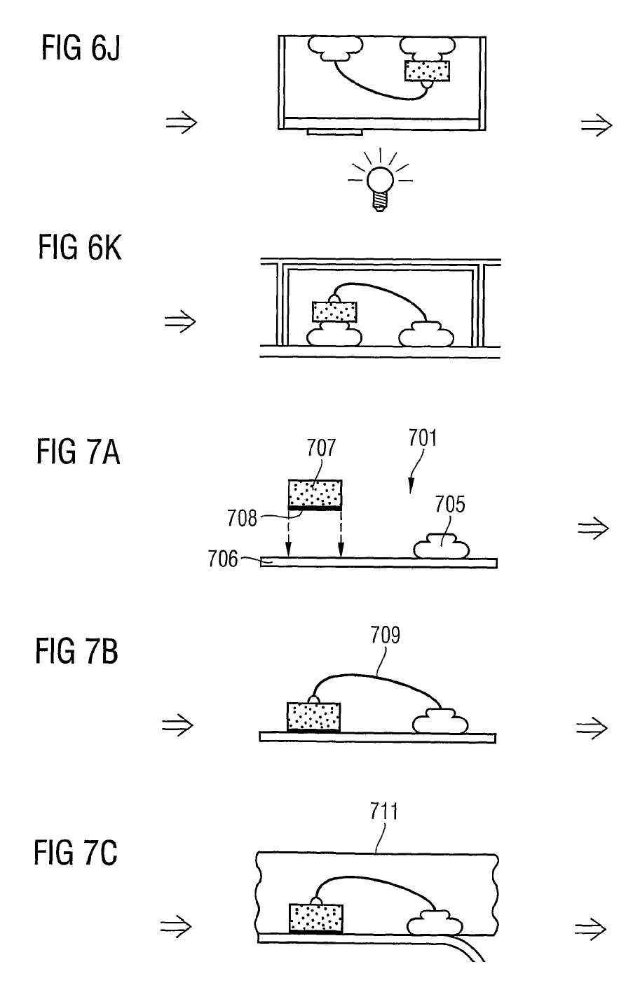

FIGS. 6a to 6k show a method according to first embodiment of the invention. In this embodiment, copper bumps, as formed by the process of FIGS. 4a and 4b are used as die pads and bond pads in a TSLP package. Referring to FIG. 6a, first of all a TSLP frame 601 is provided. In FIG. 6a, one die pad 603 and one bond pad 605 are shown on substrate 606. The die pad 603 and bond pad 605 are copper bumps formed according to the process of FIGS. 4a and 4b. On die pad 603 is an integrated circuit die 607. Just like in FIG. 2a, the die is attached to the die pad by an epoxy glue layer. Then, the die 607 is electrically connected to bond pad 605 by a wire bond 609. This is shown in FIG. 6b which corresponds to prior art FIG. 2b. Then, the die 607 and wire bonds 609 are encapsulated in an electrically insulating molding compound 611, as shown in FIG. 6c, which corresponds to prior art FIG. 2c. As before, curing is carried out to harden the molding compound. In FIG. 6d, equivalent to prior art FIG. 2d, a laser marking process is carried out to mark identification marks onto the molding compound surface. In the prior art process, the next step (FIG. 2e) was an etching step to remove the copper substrate. Then a gold layer was deposited onto the underside of the pad(s) to ensure good solder reflow later (see FIG. 2f). However, with this embodiment of the invention, those steps are not required and those steps can be replaced by a single step shown in FIG. 6e. In FIG. 6e, the organic substrate can be peeled off manually, thus no etching is required—and, after cleaning to remove any remaining adhesive residue, a non-gold layer can be applied to the underside of the copper bumps, which remain encapsulated in the cured molding compound. The layer on the underside of the copper bumps protects against oxidation and can be tin or solder or a silver alloy or a gold alloy.

Because the bumps are made from copper, gold is not necessarily required. Of course, if the bumps were made from gold, no oxidation resistant underside layer would be required at all.

Subsequent steps are the same as in the prior art: lamination (shown in FIG. 6f, equivalent to prior art FIG. 2g), dicing (shown in FIG. 6g, equivalent to prior art FIG. 2h), visual inspection (shown in FIG. 6h, equivalent to prior art FIG. 2i), electrical testing (shown in FIG. 6i, equivalent to prior art FIG. 2j), UV irradiation (shown in FIG. 6j, equivalent to prior art FIG. 2k) and taping (shown in FIG. 6k, equivalent to prior art FIG. 2l).

If we compare the process of FIGS. 6a to 6k with the prior art process of FIGS. 2a to 2l, we see that there are several advantages. Firstly, no etching is required since the substrate can be removed manually. Also, no gold plating is necessarily required; the exposed undersides of the copper bumps can be coated with tin, solder (tin and lead alloy), a silver alloy or a gold alloy, this is, obviously, much cheaper. The resulting packages also have a number of advantages associated with using bumps rather than plated pads as previously described with reference to FIGS. 4a and 4b.

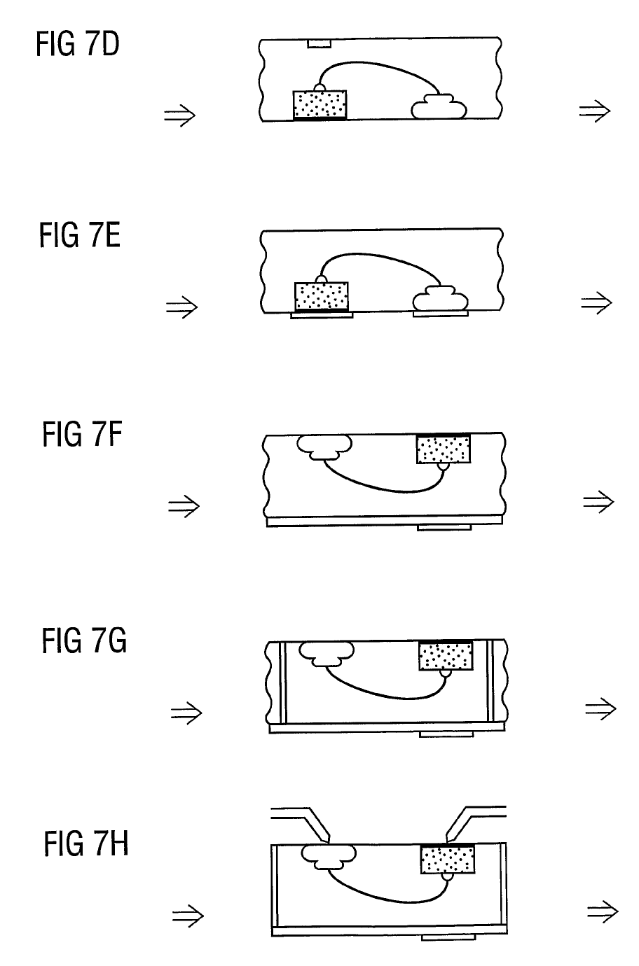

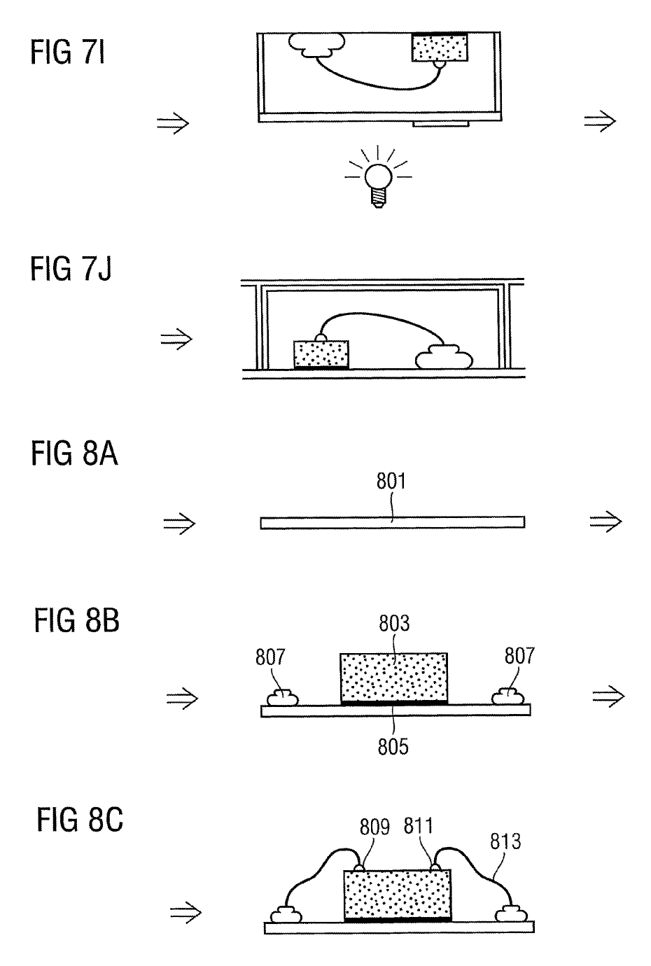

FIGS. 7a to 7j show a method according a second embodiment of the invention. In this embodiment, copper bumps as formed by the process of FIGS. 4a and 4b are used as bond pads in a TSLP package. The die, however, is attached directly to the substrate rather than to a die pad, as will be further described below. In FIG. 7a, first of all a TSLP frame 701 is provided. The bond pad 705 is a copper bump formed according to the process of FIGS. 4a and 4b. The die 707 is attached directly to the substrate 706 which is adhesive tape (such as polyimide tape). Firstly, the underside of the die is coated with a layer of metal, by sputtering, as usual. The metal may be nickel, nickel alloy, gold, gold alloy, silver or a silver alloy (or a combination of those metals). The die is then stuck to the adhesive substrate. Then, the die is electrically connected to the bond pad 705 by a wire bond 709. This is shown in FIG. 7b which corresponds to prior art FIG. 2b. Then, the die 707 and wire bonds 709 are encapsulated in an electrically insulating molding compound 711, as shown in FIG. 7c, which corresponds to prior art FIG. 2c. Curing is then carried out to harden the molding compound 711. At this stage, the adhesive tape substrate may be removed manually, as shown in FIG. 7c, or the substrate can be removed after the next step, as before. In FIG. 7d, equivalent to prior art FIG. 2d, a laser marking process is carried out to mark identification marks onto the surface of the molding compound. In the prior art process, the next step (FIG. 2e) was an etching step to remove the copper substrate. Then a gold layer was deposited onto the under surface of the pad to ensure good solder reflow later (see FIG. 2f). However, with this embodiment of the invention, no etching is required since the adhesive tape can be peeled off manually. So those two steps can be replaced with a single step, shown in FIG. 7e of cleaning the package underside (to remove any remaining adhesive) and plating the underside of the die 707 and the bond pad 705 with a layer to prevent oxidation. This layer may be tin or solder or a silver alloy or a gold alloy. Often, the cheapest composition is chosen to reduce costs. Typically, silver is used for the underside of the die and tin or solder is used for the underside of the bond pad. Then the upper surface of the molding compound 711 is laminated with a support (shown in FIG. 7f, equivalent to FIG. 2g). Then dicing is carried out to separate the array into individual units (shown in FIG. 7g, equivalent to prior art FIG. 2h). In the prior art, the next step (FIG. 2i) was a visual inspection step to check the quality of the gold plating. However, in this embodiment, that step can be skipped since the quality of the metal layer on the underside of the die is typically higher quality than the gold plate layer of the prior art. Subsequent steps are the same as in the prior art: electrical testing (shown in FIG. 7h, equivalent to prior art FIG. 2j), UV irradiation (shown in FIG. 7i, equivalent to prior art FIG. 2k) and taping (shown in FIG. 7j, equivalent to prior art FIG. 2l).

If we compare the process of FIGS. 7a to 7j with the prior art process of FIGS. 2a to 2l, we see that there are many advantages. Firstly, there are fewer processing steps which cuts down cycle time and costs. Also, no gold plating is necessarily required, which reduces costs; another cheaper composition (e.g., solder) can be used instead. Thirdly, the die can be attached to the substrate at room temperature since no curing is required as there is no epoxy glue layer. Thus, no nitrogen or forming gas is required. The resulting packages also have a number of advantages. They are thinner than the prior art packages. In this arrangement, the die thickness can be around 50 μm resulting in a package thickness of less than about 0.2 mm. (Prior art packages are typically around 0.4 mm thick.) Also the resulting packages occupy a smaller footprint.

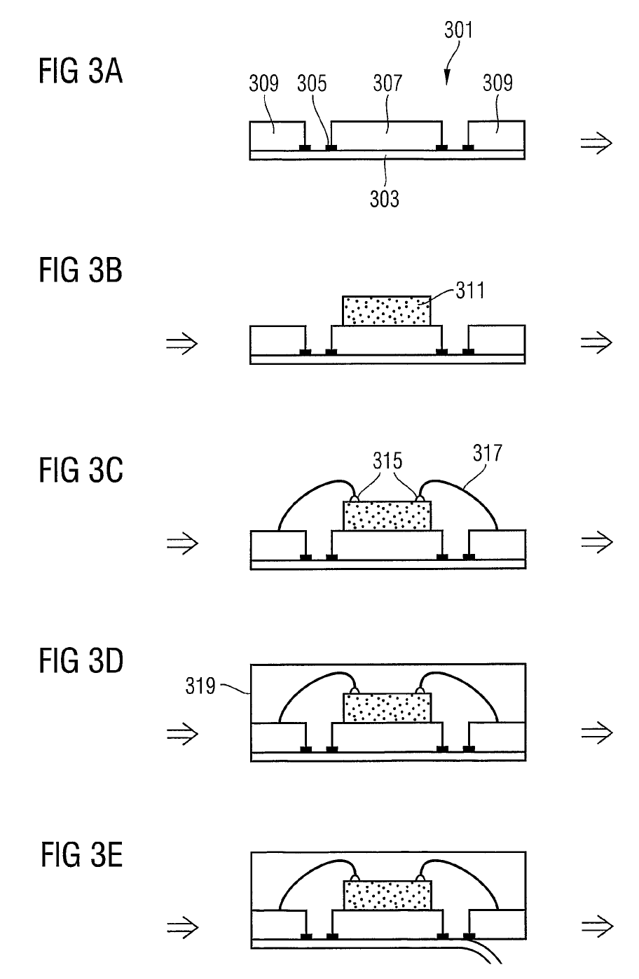

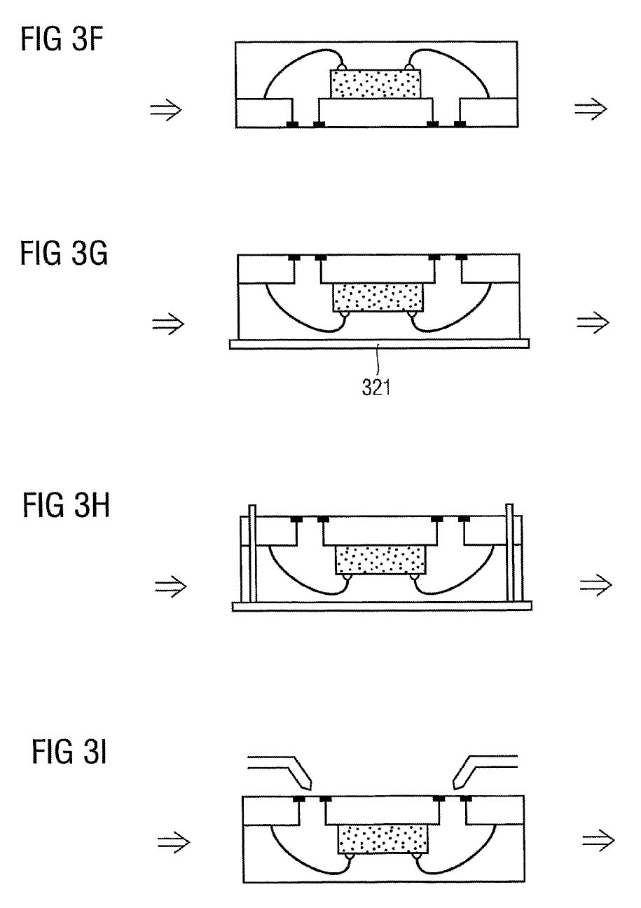

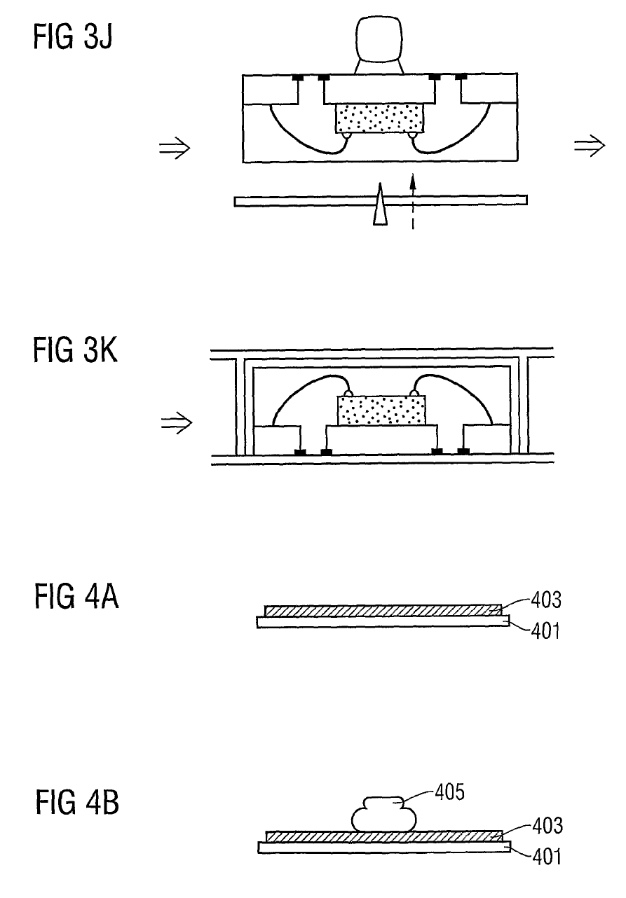

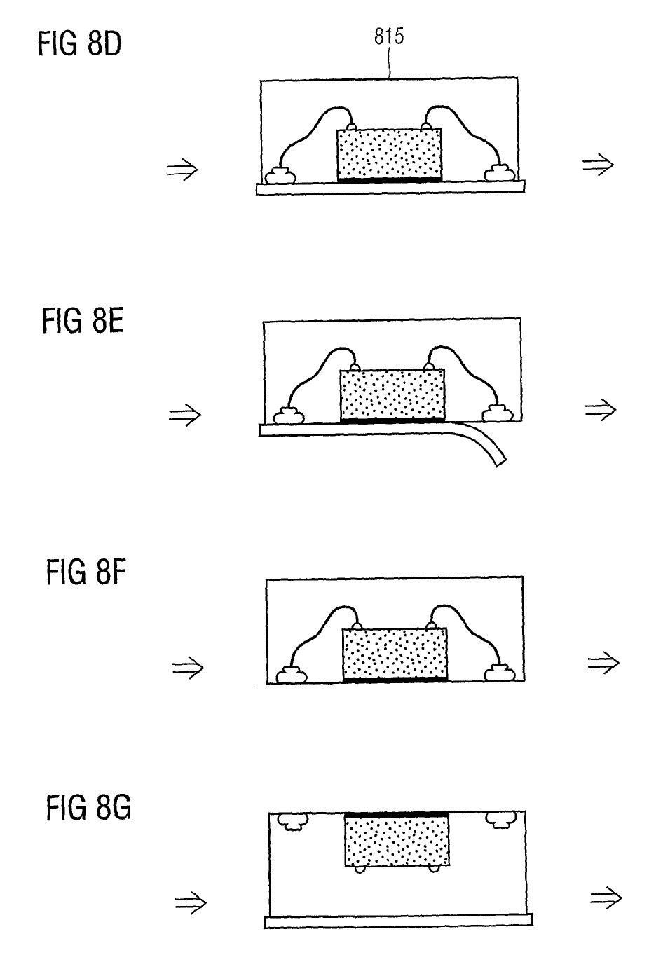

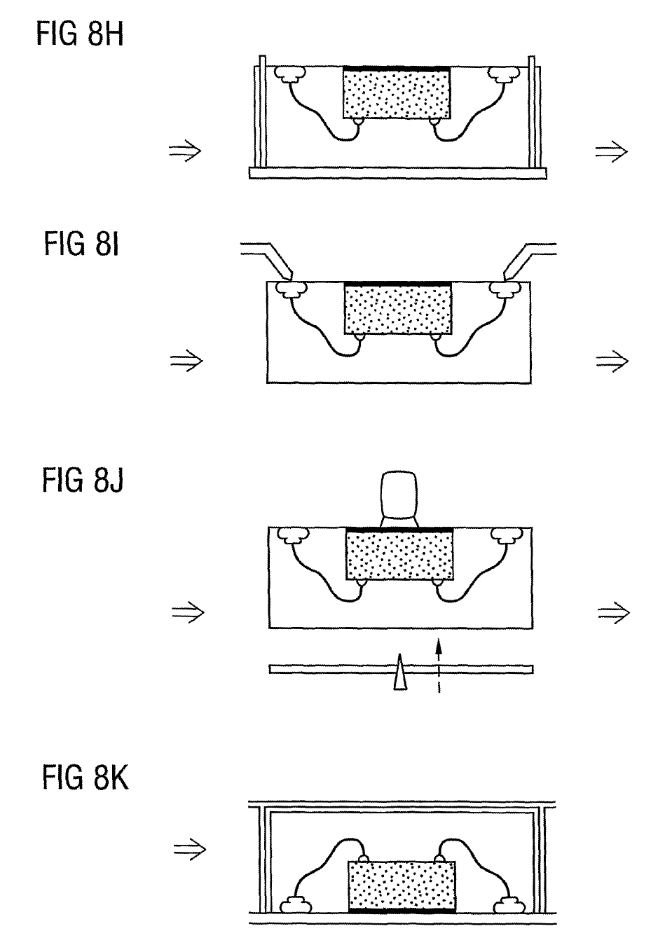

FIGS. 8a to 8k show a third embodiment of the invention. This embodiment shows a method for assembling a QFN package. Referring to FIG. 8a, an adhesive tape 801 is provided to act as a substrate. This may be UV foil or polyimide tape, for example. Referring to FIG. 8b, a die 803 is attached directly to the adhesive tape substrate 801 in a similar way as described with reference to FIG. 7a. As usual, the underside of the die 803 is coated with a layer of metal 805 before it is attached to the adhesive substrate. The metal may be nickel, a nickel alloy, gold, a gold alloy, silver or a silver alloy. Copper bumps 807, formed by the process described in FIGS. 4a and 4b, are also formed on the adhesive substrate 801. Then, electrical contacts 809, 811 on the die 803 are each connected to a respective copper bump 807 by wire bonds 813. The wire may be gold or copper. This is shown in FIG. 8c, which is equivalent to prior art FIG. 3c. Then, the die 803, copper bumps 807 and wire bonds 813 are encapsulated in an electrically insulating molding compound 815. This is shown in FIG. 8d, which is equivalent to prior art FIG. 3d. Then, a curing process is carried out to harden the molding compound 815. The adhesive substrate can then be removed from the molding compound by peeling away the substrate. This is shown in FIG. 8e which is equivalent to prior art FIG. 3e. This exposes the undersides of copper bumps 807 and the metal layer 805 on the underside of the die 803. Subsequent steps are the same as in the prior art: cleaning and plating (FIG. 8f equivalent to prior art FIG. 3f), lamination with a support (FIG. 8g equivalent to prior art FIG. 8g), dicing (FIG. 8h equivalent to prior art FIG. 3h), electrical testing (FIG. 8i equivalent to prior art FIG. 3i), pick and place (FIG. 8j equivalent to prior art FIG. 3j) and tape and reel (FIG. 8k equivalent to prior art FIG. 3k).

If we compare the process of FIGS. 8a to 8k with the prior art process of FIGS. 2a to 2l, we see that there are many advantages. Firstly, there are fewer processing steps which cuts down cycle time and costs. Secondly, no leadframe is required. Since we do not need to worry about the leadframe warping, the molding compound used can be a clear compound. The resulting packages also have a number of advantages. They have a reduced height since the die is attached directly to the substrate and there is no leadframe. Also they occupy a smaller footprint.

The arrangements shown in FIGS. 7a to 7j and 8a to 8k may also be applied to a stacked TSLP or QFN package and a possible arrangement of copper bumps for a stacked package is shown in FIG. 5b. In that case, the upper IC may be connected to the lower IC by adhesive in a similar way as the lower IC is attached to the substrate. This reduces the height and footprint of the resulting package.

Several embodiments have been described but other arrangements can be envisaged. For example, in FIGS. 7a to 7j, the die is attached directly to the substrate rather than to a die pad. In that case, although there are advantages in the bond pad being a copper bump, the bond pad could, of course, be a bond pad formed by plating, as described with reference to FIGS. 1a to 1h. Other similar variations are also possible. Also, the particular substances used for the various parts of the structure (e.g., the substrate, the die pads, bond pads, the layers on the pads) are not limited to those described above; any suitable substance could be used as will be understood by the skilled person.

What is claimed is:

1. An integrated circuit package comprising:
an integrated circuit having a surface at least partially covered by a metal layer;
at least one connection point;
at least one connector electrically connecting the integrated circuit with the at least one connection point; and
encapsulating material encapsulating the at least one connector, at least some of the integrated circuit and at least some of the at least one connection point, such that a contact surface of the at least one connection point and the metal layer on the integrated circuit are exposed outside the encapsulating material.

2. The integrated circuit package according to claim 1, wherein the metal layer is coated with a layer of oxidation resistant material.

3. The integrated circuit package according to claim 2, wherein the oxidation resistant material comprises a noble metal.

4. The integrated circuit package according to claim 1, wherein the exposed contact surfaces of the at least one connection point are coated with a layer of oxidation resistant material.

5. The integrated circuit package according to claim 4, wherein the oxidation resistant material comprises a noble metal.

6. The integrated circuit package according to claim 1, wherein the at least one connection point comprises a non-layered drop of metal.

7. A method for manufacturing an integrated circuit package, the method comprising:
providing an adhesive surface;
forming at least one connection point on the adhesive surface;
providing an integrated circuit, the integrated circuit having a surface at least partially covered by a metal layer;
attaching the metal layer on the integrated circuit to the adhesive surface;
electrically connecting the integrated circuit to the at least one connection point with at least one connector;
encapsulating, with an encapsulating material, the at least one connector, at least some of the integrated circuit and at least some of the at least one connection point; and
after encapsulating, removing the adhesive surface so as to expose a contact surface of the at least one connection point and the metal layer on the integrated circuit.

8. The method according to claim 7, wherein removing the adhesive surface comprises peeling the adhesive surface away from the encapsulating material.

9. The method according to claim 7, wherein the metal layer on the integrated circuit comprises nickel.

10. The method according to claim 7, further comprising after removing the adhesive surface, coating the exposed metal layer with a layer of oxidation resistant material.

11. The method according to claim 7, further comprising after removing the adhesive surface, coating at least one of the exposed contact surfaces of the at least one connection point with a layer of oxidation resistant material.

12. The method according to claim 7, wherein forming the at least one connection point on the adhesive surface comprises:
melting metal wire to form at least one globule; and
pressing the at least one globule onto the adhesive surface to form the at least one connection point.

13. An integrated circuit package obtained by the method of claim 7.

14. An integrated circuit package comprising:
an integrated circuit;
at least one connection point, the at least one connection point comprising a non-layered drop of metal;
at least one connector electrically connecting the integrated circuit with the at least one connection point; and
encapsulating material encapsulating the at least one connector, at least some of the integrated circuit and at least some of the at least one connection point, such that a contact surface of the each connection point is exposed outside the encapsulating material.

15. The integrated circuit package according to claim 14, wherein the exposed contact surfaces of the at least one connection point are coated with a layer of oxidation resistant material.

16. The integrated circuit package according to claim 15, wherein the oxidation resistant material comprises a noble metal.

17. The integrated circuit package according to claim 14, wherein the integrated circuit has a surface at least partially covered by a metal layer.

18. The integrated circuit package according to claim 17, wherein the metal layer on the integrated circuit is exposed outside the encapsulating material.

19. The integrated circuit package according to claim 14, wherein the integrated circuit is attached to and electrically in contact with an integrated circuit connection point.

20. The integrated circuit package according to claim 19, wherein a contact surface of the integrated circuit connection point is exposed outside the encapsulating material.

21. The integrated circuit package according to claim 19, wherein the integrated circuit connection point comprises a non-layered drop of metal.

22. The integrated circuit package according to claim 19, wherein the integrated circuit connection point comprises a plurality of metal layers.

23. A method for manufacturing an integrated circuit package, the method comprising:
providing a substrate;
melting metal wire to form at least one globule and pressing the at least one globule onto the substrate, the at least one globule forming at least one connection point;
providing an integrated circuit;
electrically connecting the integrated circuit to the at least one connection point with at least one connector;
encapsulating, with an encapsulating material, the at least one connector, at least some of the integrated circuit and at least some of the at least one connection point; and
after encapsulating, removing the substrate so as to expose a contact surface of the at least one connection point.

24. The method according to claim 23, further comprising after removing the substrate, coating at least one of the exposed contact surfaces of the at least one connection point with a layer of oxidation resistant material.

25. The method according to claim 23, wherein the integrated circuit has a surface at least partially covered by a metal layer.

26. The method according to claim 25, further comprising before encapsulating, attaching the metal layer on the integrated circuit to the substrate, wherein, after the substrate is removed, the metal layer on the integrated circuit is exposed outside the encapsulating the material.

27. The method according to claim 23, further comprising forming an integrated circuit connection point on the substrate.

28. The method according to claim 27, further comprising attaching and electrically connecting the integrated circuit to the integrated circuit connection point.

29. The method according to claim 27, wherein, after the substrate is removed, a contact surface of the integrated circuit connection point is exposed outside the encapsulating material.

30. The method according to claim 27, wherein forming the integrated circuit connection point on the substrate comprises:
melting metal wire to form at least one globule; and
pressing the at least one globule onto the substrate.

31. The method according to claim 27, wherein forming the integrated circuit connection point on the substrate comprises plating a plurality of metal layers onto the substrate.

32. An integrated circuit package obtained by the method of claim 23.
